(19) United States
(12) Patent Application Publication
(10) Pub. No.: US 2024/0381604 A1
(43) Pub. Date: Nov. 14, 2024

(54) INFORMATION PROCESSING DEVICE, MOUNTING SYSTEM, AND INFORMATION PROCESSING METHOD

(71) Applicant: FUJI CORPORATION, Chiryu (JP)

(72) Inventors: Mitsuru SANJI, Toyota-shi (JP); Kenji HARA, Kariya-shi (JP)

(73) Assignee: FUJI CORPORATION, Chiryu (JP)

(21) Appl. No.: 18/692,418

(22) PCT Filed: Oct. 13, 2021
(86) PCT No.: PCT/JP2021/037914

§ 371 Date: Mar. 15, 2024

(51) Int. Cl. H05K 13/08; G06F 1/18

(52) U.S. Cl. CPC H05K 13/0882; G06F 1/187

(57) ABSTRACT

An information processing device of the present disclosure is an information processing device used in a mounting system including a mounting device configured to perform mounting processing on a processing target object, the information processing device including: a control section configured to set, for a magazine including multiple slots in which component supply devices configured to supply components are installed, an installation set including an installation slot in which the component supply device is installed and a vacant slot in which the component supply device is not installed, and output the set installation set.

### TECHNICAL FIELD

The present description discloses an information processing device, a mounting system, and an information processing method.

### BACKGROUND ART

Conventionally, for example, in a mounting system that mounts a component on a processing target object such as a board, there has been proposed a storage device that stores a feeder as a component supply device, in which a region is divided and used for each purpose such as next production serving, component shortage supply, and used component recovery (for example, refer to Patent Literature1). In this device, it is possible to further improve the convenience of the work of attaching and detaching the component supply device, which is used or not used for production, to and from the storage device.

### PATENT LITERATURE

Patent Literature 1: WO2020/165966

### BRIEF SUMMARY

### Technical Problem

In Patent Literature 1 described above, there is a case where the component supply devices are collectively served for an installation section base provided in the storage device using the magazine. Alternatively, the component supply devices may be collectively served for an installation section provided in the mounting device by using the magazine. For example, in the mounting device, unexpected shortage may occur in the component being produced, and in such a situation, a countermeasure as to how the component supply device is supplied is required.

The present disclosure has been made in view of such a problem, and a main object thereof is to provide an information processing device, a mounting system, and an information processing method capable of supplying a component supply device more appropriately.

### Solution to Problem

An information processing device, a mounting system, and an information processing method disclosed in the present description adopt the following means in order to achieve the main object described above.

The present disclosure relates to an information processing device used in a mounting system including a mounting device configured to perform mounting processing on a processing target object, the information processing device including: a control section configured to set, for a magazine including multiple slots in which component supply devices configured to supply components are installed, an installation set including an installation slot in which the component supply device is installed and a vacant slot in which the component supply device is not installed, and output the set installation set.

In the information processing device, for the magazine including the multiple slots in which component supply devices configured to supply the components are installed, the installation set including the installation slot in which the component supply device is installed and the vacant slot in which the component supply device is not installed is set, and the set installation set is output. For example, in the mounting system, when the magazine in which the multiple component supply devices are installed is used, the installation of the component supply devices in all the slots of the magazine is more efficient in serving the component supply devices. Meanwhile, in the mounting device, the unexpected component shortage may occur, and there is a problem in how the component supply device is served in this case. As described above, when the information processing device performs operation with the magazine in which the component supply devices are fully installed, in a case where an unexpected component supply device is added to the magazine, an enormous amount of recalculation is required for a serving plan in the production, and furthermore, there may be a case where the component supply device installed in the magazine is exchanged or the like, and it is not possible to sufficiently take a countermeasure. In the information processing device of the present disclosure, since the component supply device is served by the installation set including the vacant slot, it is possible to flexibly take a countermeasure for an unexpected component shortage or the like, and to more appropriately supply the component supply device.

### BRIEF DESCRIPTION OF DRAWINGS

FIG. 1 is a schematic diagram illustrating an example of mounting system 10.

FIG. 2 is a diagram illustrating schematic configurations of mounting device 15 and loader 18.

FIGS. 3A and 3B are diagrams illustrating an example of feeders 60A and 60B.

FIG. 4 is a diagram illustrating schematic configurations of storage device 13 and automatic conveyance vehicle 16.

FIGS. 5A and 5B are diagrams illustrating a schematic configuration of magazine 65.

FIGS. 6A and 6B are diagrams illustrating an example of installation set information 45 stored in storage section 42.

FIG. 7 is a flowchart illustrating an example of a feeder supply plan setting processing routine.

FIG. 8 is a flowchart illustrating an example of a mounting processing routine.

FIG. 9 is a flowchart illustrating an example of an installation set information update processing routine.

FIGS. 10A and 10B are diagrams illustrating an example in which unexpected feeder 60 is supplied to the magazine.

FIG. 11 is a diagram illustrating an example of another preparation facility 17A.

### DESCRIPTION OF EMBODIMENTS

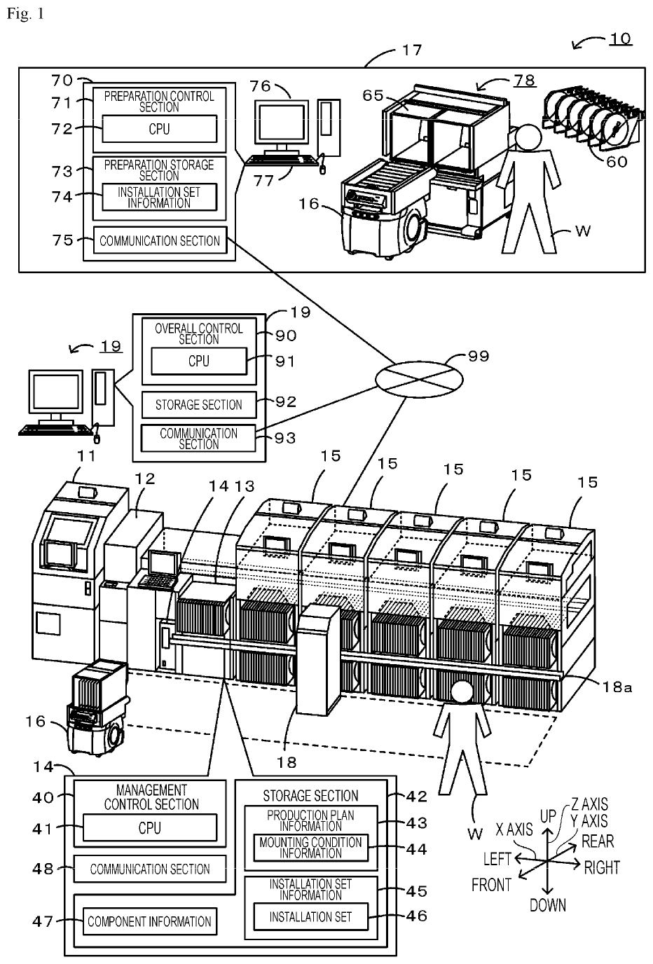

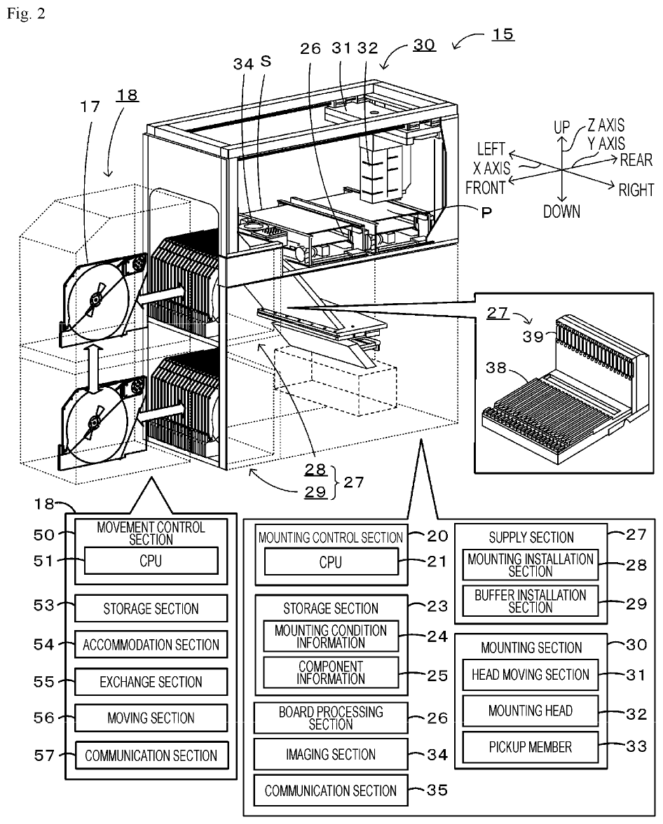

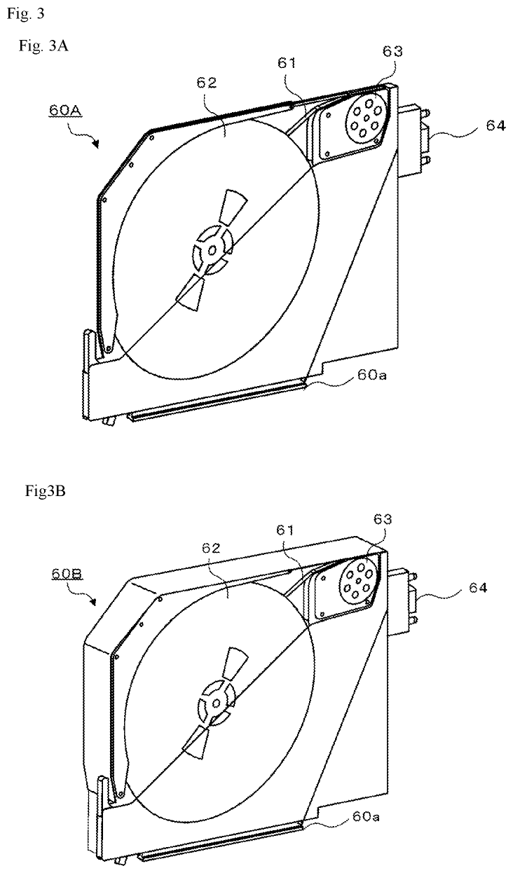

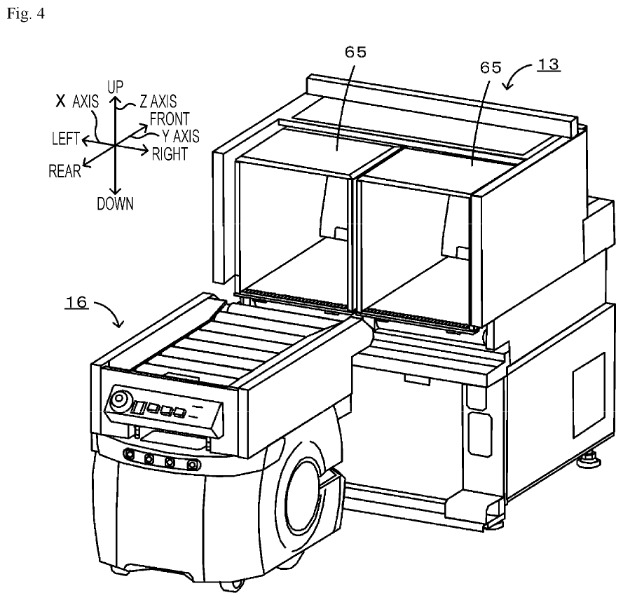

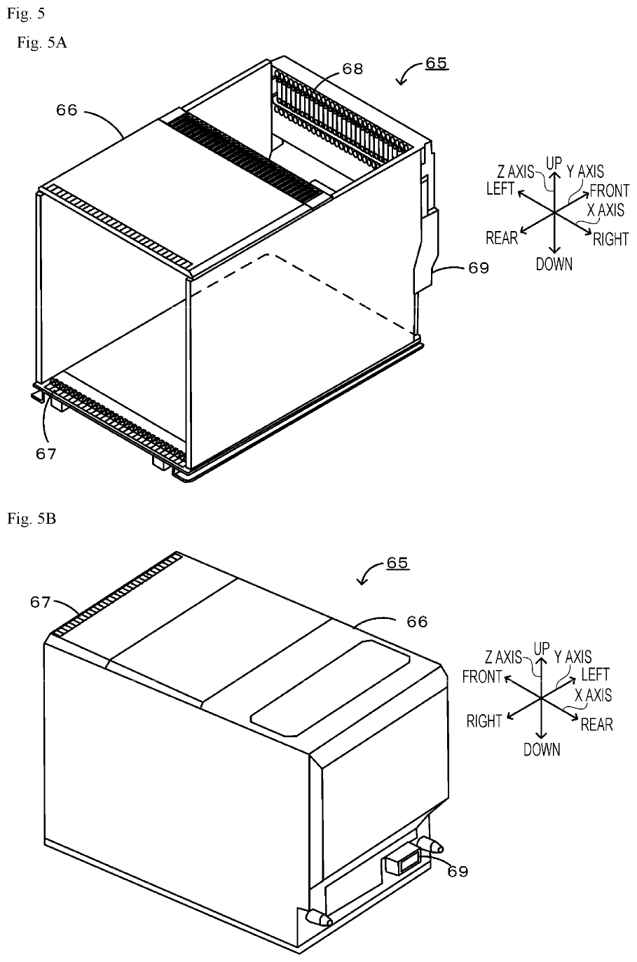

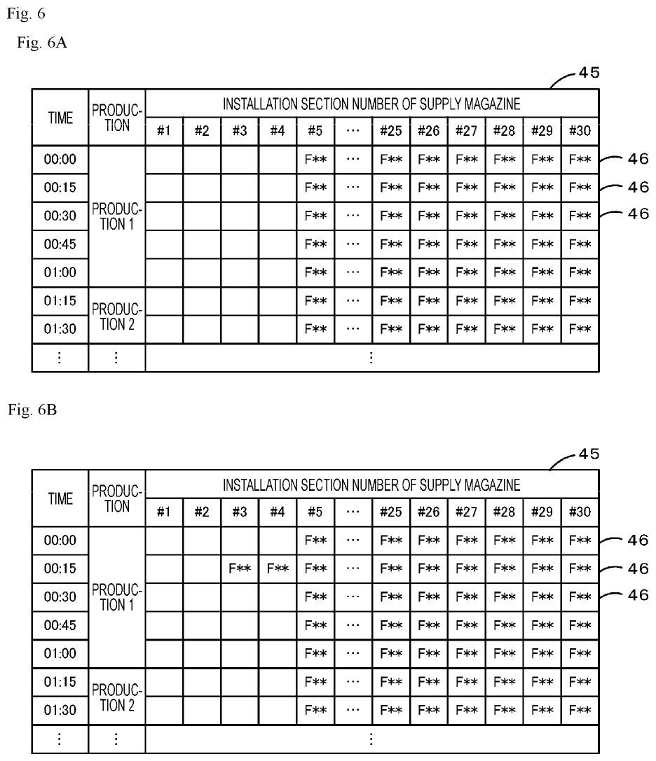

The present embodiment will be described below with reference to drawings. FIG. 1 is a schematic diagram illustrating an example of mounting system 10 of the present disclosure. FIG. 2 is a diagram illustrating schematic configurations of mounting device 15 and loader 18 that is a mobile work device. FIGS. 3A and 3B are diagrams of feeder 60, FIG. 3A is an example of feeder 60A, and FIG. 3B is an example of feeder 60B. FIG. 4 is a diagram illustrating schematic configurations of storage device 13 and automatic conveyance vehicle 16. FIGS. 5A and 5B are diagrams illustrating a schematic configuration of magazine 65 installed in storage device 13, FIG. 5A is a perspective view from a front side, and FIG. 5B is a perspective view from a rear side. FIGS. 6A and 6B are diagrams illustrating an example of installation set information 45 stored in storage section 42, FIG. 6A is a diagram of the beginning of the setting, and FIG. 6B is a diagram in which unexpected feeder 60 is added. In the present embodiment, a left-right direction (X axis), a front-rear direction (Y axis), and an up-down direction (Z axis) are as illustrated in FIGS. 1, 2, 4, 5A, and 5B.

Mounting system 10 is configured, for example, as a production line in which mounting devices 15 performing mounting processing of components P on board S as a processing target object are arranged in a conveyance direction of board S. Here, the description will be made using board S as the processing target object, but the configuration is not particularly limited as long as the processing target object is an object on which component is mounted, and may be a base material having a three-dimensional shape. As illustrated in FIG. 1, mounting system 10 includes printing device 11, printing inspection device 12, storage device 13, management device 14, mounting device 15, automatic conveyance vehicle 16, preparation facility 17, loader 18, overall control device 19, and the like. Printing device 11 is a device that prints viscous fluid such as a solder paste on board S. Printing inspection device 12 is a device that inspects a state of printed solder or board S.

Mounting device 15 is a device that picks up the components and mounts the components on board S. Mounting device 15 includes mounting control section 20, storage section 23, board processing section 26, supply section 27, mounting section 30, imaging section 34, and communication section 35. Mounting control section 20 is configured as a microprocessor centered on CPU 21, and controls the entire device, as illustrated in FIG. 2. Mounting control section 20 outputs control signals to board processing section 26, supply section 27, or mounting section 30 to cause mounting section 30 to pick up the components, and receives signals from board processing section 26, supply section 27, or mounting section 30. Storage section 23 stores mounting condition information 24, component information 25, and the like. Mounting condition information 24 is a production job, and includes information on component P, information on a disposition order and a disposition position for mounting components P on board S, and an installation position of feeder 60 for picking up the component. A pickup order, a disposition order, and the like having high mounting efficiency are created by overall control device 19, and mounting condition information 24 is transmitted from overall control device 19 and stored in storage section 23. Component information 25 is information including, for example, the type of feeder 60 currently installed in supply section 27 of mounting device 15, component information including a component type and a remaining number of components possessed by feeder 60, and the like. Component information 25 is appropriately updated to the current content when component P is used, or feeder 60 is installed or removed.

Board processing section 26 is a unit that performs carrying in of board S, conveyance of board S, fixation of board S at a mounting position, and carrying out of board S. Board processing section 26 includes a pair of conveyor belts that are provided at intervals in the front-rear direction while being stretched in the left-right direction. Board S is conveyed by the conveyor belts. Board processing section 26 includes two pairs of the conveyor belts, and can convey and fix two boards S simultaneously.

Supply section 27 is a unit that supplies the components to mounting section 30. Supply section 27 installs feeder 60 as a component supply device on one or more installation sections. As illustrated in FIG. 2, supply section 27 has two upper and lower installation sections in which feeders 60 can be installed on the front side. The upper stage is mounting installation section 28 from which the component can be picked up by mounting section 30, and the lower stage is buffer installation section 29 from which the component cannot be picked up by mounting section 30. Here, mounting installation section 28 and buffer installation section 29 are collectively referred to as installation sections. Feeder 60 from which the component is picked up by mounting head 32 is installed in mounting installation section 28. When there is a vacancy in mounting installation section 28, feeder 60 for setup change that is used in the next production is served in advance. Buffer installation section 29 is used in a case where feeder 60 that is to be used next or used feeder 60 is temporarily stored. Buffer installation section 29 is served in advance with feeder 60 for supply that is exchanged due to the component shortage, feeder 60 for setup change that is used in the next production, or the like. Supply section 27 has an installation section including multiple slots 38 which are arranged in the X direction at predetermined intervals and into which rail members 60a of feeders 60 are inserted, and connection sections 39 into which connectors 64 provided at the distal end of feeders 60 are inserted.

Mounting section 30 is a unit that picks up component P from supply section 27 and puts component P on board S fixed to board processing section 26. Mounting section 30 includes head moving section 31, mounting head 32, and pickup member 33. Head moving section 31 includes a slider moving by being guided by guide rails in the XY directions, and a motor driving the slider. Mounting head 32 picks up one or more components P and is moved in the XY directions by head moving section 31. Mounting head 32 is detachably installed in the slider. Nozzles as one or more pickup members 33 are detachably installed on a lower surface of mounting head 32. the nozzle is configured to pick up component P by using a negative pressure. Pickup member 33 that picks up component P may be a mechanical chuck for mechanically holding component P instead of the nozzle.

Imaging section 34 is a device that captures an image of one or more components P, which are picked up and held by mounting head 32, from below. Imaging section 34 captures the image of component P when mounting head 32 that picks up component P passes above imaging section 34, and outputs the captured image to mounting control section 20. Mounting control section 20 detects a pickup state of component P using the captured image. Communication section 35 is an interface that exchanges information with an external device such as management device 14 or overall control device 19.

As illustrated in FIGS. 3A and 3B, feeder 60 is configured as the component supply device, and includes rail member 60a, reel 62 on which tape 61 is wound, feeding mechanism 63, connector 64, and a controller (not illustrated). In the installation section of supply section 27, multiple types of feeders 60A and 60B having different widths can be installed in accordance with a difference in size of the held component type. Feeder 60A and feeder 60B are collectively referred to as feeder 60. Feeder 60 is a cassette type tape feeder that accommodates reel 62. Tape 61 holds component P. Rail member 60a is a rail-shaped portion to be inserted into a groove formed in the slot of each installation section. The controller stores information, such as ID of the tape provided in feeder 60, the component type, or the remaining number of components. When feeder 60 is connected to any of the devices, the controller transmits information on feeder 60 to the control section of the device.

Magazine 65 is an accommodation case capable of accommodating multiple feeders 60. As illustrated in FIGS. 4, 5A, and 5B, magazine 65 includes housing 66, slot 67, feeder connection section 68, and connector 69 connected to an external device. Housing 66 is a rectangular accommodation case. Multiple slots 67 are provided along the left-right direction in an edge portion on a rear entrance side of housing 66. Rail member 60a of feeder 60 is inserted into slot 67, and slot 67 holds feeder 60 in appropriate position and posture. Connection section 68 is connected to connector 64 of feeder 60 when feeder 60 is inserted into slot 67. Connector 69 can be connected to connector (not illustrated) of storage device 13 or storage device 78 as an external device. When magazine 65 is installed in storage device 13 or storage device 78, magazine 65 is electrically connected to the control section of each device via connection section 68 and connector 69, and exchanges information. Magazine 65 has, for example, 30 slots 67, and is configured such that up to 30 general feeders 60 corresponding to the number of slots can be installed. By using magazine 65, a large number of feeders 60 can be collectively moved by one movement by automatic conveyance vehicle 16.

Storage device 13 is a storage place where feeder 60 used in mounting device 15 is temporarily stored by installing magazine 65. Storage device 13 is provided adjacent to a conveyance device between printing inspection device 12 and mounting device 15. As illustrated in FIG. 4, storage device 13 includes magazine housing sections arranged side by side in the left-right direction, and management device 14. As illustrated in FIG. 4, two magazines 65 can be installed in the magazine housing section. In addition, multiple rollers for moving an object along an entrance/exit direction are pivotally supported on a bottom surface of the magazine housing section, and magazine 65 is put in and out by the rollers. Storage device 13 can be connected to connector 69 provided on a back side of magazine 65. When connector 69 of magazine 65 is connected, management device 14 that controls storage device 13 and magazine 65 can communicate with each other, and management device 14 acquires information on magazine 65, for example, information on component P held by feeder 60 set in slot 67, information on whether feeder 60 is set in slot 67, and the like. In storage device 13, magazine 65 (feeder 60) may be carried by automatic conveyance vehicle 16, or magazine 65 (feeder 60) may be carried by a worker.

Management device 14 is configured as an information processing device that manages feeders 60 stores, for example, execution data executed by loader 18, and manages storage device 13 or loader 18. As illustrated in FIG. 1, management device 14 includes management control section 40, storage section 42, communication section 48, a display section, and an input device. The display section is a liquid crystal screen that displays various information. The input device includes a keyboard, a mouse, and the like through which worker W inputs various commands. Communication section 48 is an interface that performs communication with an external device. Management control section 40 is configured as a microprocessor centered on CPU 41, and controls the entire device. Storage section 42 stores, as information used to control storage device 13 or loader 18, production plan information 43 including multiple pieces of mounting condition information 44, installation set information 45 including installation set 46, component information 47 including the type and the remaining number of components P, and the like. Mounting condition information 44 includes information on the mounting processing for producing specific board S, and is transmitted from overall control device 19 and stored in storage section 42. Installation set information 45 is information on the installation position and a supply timing, in magazine 65, of feeder 60 supplied in accordance with the use of component P, and is created based on production plan information 43. As illustrated in FIGS. 6A and 6B, installation set information 45 is information in which an installation section number of magazine 65, an identifier of feeder 60 installed in the installation section, and/or an identifier of component P held by feeder 60, are associated with each production time of board S. Installation set information 45 includes one or more installation sets 46 associated with each supply time. Installation set information 45 is output to preparation PC 70 of preparation facility 17, and is used to prepare feeder 60 or magazine 65 in preparation facility 17.

Automatic conveyance vehicle 16 automatically conveys feeder 60, members used in mounting system 10, or the like between storage device 13 disposed in the production line and storage device 78 of preparation facility 17. As illustrated in FIG. 4, automatic conveyance vehicle 16 includes a transfer device disposed on an upper surface and capable of transferring magazine 65 to and from storage device 13 or storage device 78, and a control section. Automatic conveyance vehicle 16 is configured as, for example, an automatic guided vehicle (AGV) or an autonomous mobile robot (AMR). The transfer device includes multiple rollers and moves magazine 65 back and forth. The control section is a controller including CPU and a storage section, and controls the entire device.

Preparation facility 17 is an area for preparing exchangeable members such as consumables used in mounting system 10 and the like. Preparation facility 17 is a warehouse and stores reel 62, feeder 60, or the like. In preparation facility 17, in a case of use in mounting device 15, worker W performs work of setting reel 62 to feeder 60 and registering information thereof in the controller of feeder 60. As illustrated in FIG. 1, in preparation facility 17, preparation PC 70 and storage device 78 are disposed. Preparation PC 70 is a device that manages work in preparation facility 17, and includes preparation control section 71, preparation storage section 73, communication section 75, display section 76, and input device 77. Preparation control section 71 is configured as a microprocessor centered on CPU 72, and controls the entire device. In preparation storage section 73, installation set information 74 and the like similar to installation set information 45 are stored as information used for preparation work of magazine 65. Installation set information 74 includes the type and the timing of feeder 60 installed in magazine 65 for supply, and is transmitted from management device 14 and stored in preparation storage section 73. Communication section 75 is an interface that performs communication with an external device. Display section 76 is a liquid crystal screen that displays various information. Input device 77 includes a keyboard, a mouse, and the like through which worker W inputs various commands. Storage device 78 is a device that installs and stores magazine 65 for supply or after use. Here, storage device 78 has configurations similar to those of storage device 13, and the detailed description thereof will not be repeated. Worker W performs work of installing feeder 60 for supply in magazine 65 installed in storage device 78 while checking the contents of installation set information 74. Automatic conveyance vehicle 16 moves magazine 65 for which preparation for supply is completed to storage device 13. Automatic conveyance vehicle 16 moves magazine 65 after use from storage device 13 to storage device 78.

Loader 18 is a mobile work device, and is a device that is moved within a movement region in front of mounting system 10 (see a dotted line in FIG. 1) and automatically recovers and supplies feeders 60 of mounting device 15. As illustrated in FIG. 2, loader 18 includes movement control section 50, storage section 53, accommodation section 54, exchange section 55, moving section 56, and communication section 57. Movement control section 50 is configured as a microprocessor centered on CPU 51, and controls the entire device. Movement control section 50 controls the entire device so that feeder 60 is recovered from supply section 27 or feeder 60 is supplied to supply section 27, and feeder 60 is moved to and from storage device 13. Storage section 53 is, for example, HDD that stores various data such as a processing program. Accommodation section 54 has an accommodation space in which feeders 60 are accommodated. Accommodation section 54 is configured to accommodate, for example, four feeders 60. Exchange section 55 is a mechanism that puts feeder 60 in and out as well as moving feeder 60 in the up-down direction (see FIG. 2). Exchange section 55 has a clamp section that clamps feeder 60, a Y-axis slider that moves the clamp section in the Y axis direction (front-rear direction), and a Z-axis slider that moves the clamp section in the Z axis direction (up-down direction). Exchange section 55 executes installation and removal of feeder 60 in mounting installation section 28, and installation and removal of feeder 60 in buffer installation section 29. Moving section 56 is a mechanism that moves loader 18 in the X axis direction (left-right direction) along X axis rail 18a disposed in front of mounting device 15. Communication section 57 is an interface that exchanges information with an external device such as management device 14 or mounting device 15. Loader 18 outputs a current position or executed work contents to management device 14.

Overall control device 19 is configured as a server that creates and manages information used by each device of mounting system 10, for example, production plan information 43. As illustrated in FIG. 1, overall control device 19 includes overall control section 90, storage section 92, and communication section 93. Overall control section 90 is configured as a microprocessor centered on CPU 91, and controls the entire device. Storage section 42 stores, for example, the production plan information including the multiple pieces of mounting condition information as the information used in mounting system 10. Communication section 93 is an interface that performs communication with an external device. In mounting system 10, each device exchanges information via network 99 such as LAN or the Internet.

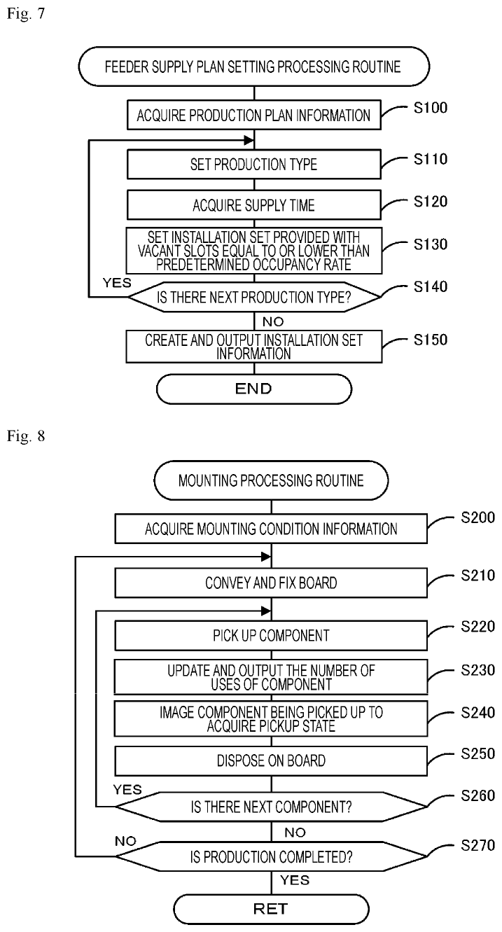

Next, an operation of mounting system 10 of the present embodiment configured as described above, that is, processing of setting, in advance, a plan for supplying feeders 60 to storage device 13 will be described. FIG. 7 is a flowchart illustrating an example of a feeder supply plan setting processing routine executed by CPU 41 of management control section 40 provided in management device 14. This routine is stored in storage section 42 of management device 14 and executed before the start of the production processing of mounting system 10. When this routine is started, first, CPU 41 reads out and acquires production plan information 43 from storage section 42 (S100), and sets a production type (board type to be produced) (S110). CPU 41 sets the board types to be produced in the order defined in production plan information 43.

Next, CPU 41 acquires the supply time of each feeder 60 based on mounting condition information 44 of the set production type (S120). CPU 41 may set, as the supply time, time at which magazine 65 is fed out from preparation facility 17 during setup change at which production is switched or during component shortage. CPU 41 can obtain setup change time based on production switch time set in advance. Further, CPU 41 can calculate component shortage time of feeder 60 from, for example, standard pickup movement time of component P, the number of mounted components of feeder 60, the number of uses of component P on board S, or the like. The supply time may be, for example, time at which preparation for installing feeder 60 in magazine 65 is completed, in time for the acquired component shortage time. Next, CPU 41 sets installation set 46 in association with the supply time set in advance (S130). The supply time is set based on an interval of time in which worker W can install all feeders 60 in magazine 65, such as 10 minutes, 15 minutes, or 20 minutes. In addition, CPU 41 sets installation set 46 to which feeder 60 to be supplied is supplied at each supply time, and sets installation set 46 to which feeder 60 that faces the component shortage next is moved up and supplied when there is a vacant slot other than a reserved vacant slot. In this way, CPU 41 subsequently sets installation set 46 corresponding to each time.

Here, CPU 41 sets, for magazine 65 having multiple slots 67 in which feeders 60 for supplying components P are installed, installation set 46 including the installation slot in which feeder 60 is installed and the vacant slot in which feeder 60 is not installed. In this case, CPU 41 may set the vacant slot for magazine 65 and set the installation slot for remaining slot 67 based on production plan information 43 (mounting condition information 44). Further, CPU 41 may set the vacant slot of magazine 65 in a range equal to or lower than a predetermined occupancy rate set in advance. For example, the occupancy rate of the vacant slot is preferably higher when unexpected feeder 60 is temporarily incorporated, and may be equal to or higher than 5%, equal to or higher than 10%, equal to or higher than 12.5%, or the like. For example, it is preferable that the occupancy rate of the vacant slot is lower when executing the component supply in a normal state because it is more efficient, and for example, the occupancy rate may be equal to or lower than 20%, equal to or lower than 15%, equal to or lower than 12.5%, or equal to or lower than 10%. The occupancy rate can be appropriately set to an appropriate range in accordance with the efficiency in a normal state or the ease of handling in an emergency. Further, multiple types of feeders 60 having different widths can be installed in magazine 65, but CPU 41 may set the vacant slot in which at least one feeder 60 can be installed. That is, it is preferable that CPU 41 provide the vacant slot in which at least one feeder 60 having the largest width can be installed. Further, multiple types of feeders 60 having different widths can be installed in magazine 65, but CPU 41 may set the vacant slot in which multiple standard feeders 60 can be installed. Standard feeder 60 may be feeder 60 (for example, feeder 60A) having a width for holding component P whose number of uses is greater than those of other components P. In addition, for example, in storage device 13, CPU 41 may set a side far from mounting device 15 as the vacant slot (see FIGS. 1 and 6A). In this way, the movement efficiency of feeder 60 by loader 18 can be enhanced. In this way, CPU 41 sets installation set 46 that always includes the vacant slot in the initial setting.

When installation set 46 is set, CPU 41 determines whether there is the next production type (S140), and when there is the next production type, CPU 41 executes the processing of S110 and thereafter. That is, CPU 41 sets the next production type in S110, and sets installation set 46 in which the vacant slot is reserved in accordance with the supply time. On the other hand, when there is no next production type in S140, installation set information 45 including installation sets 46 corresponding to all the set supply times is created and stored in storage section 42, created installation set information 45 is output to preparation PC 70 (S150), and this routine is finished. In preparation PC 70 that acquires installation set information 45, installation set information 45 is displayed on display section 76, and is used for the preparation work of supply magazine 65 of worker W.

Next, mounting processing in which mounting device 15 mounts component P on board S will be described. FIG. 8 is a flowchart illustrating an example of a mounting processing routine executed by CPU 21 of mounting control section 20 provided in mounting device 15. This routine is stored in storage section 23 of mounting device 15 and executed in accordance with a start instruction from worker W. When this routine is started, first, CPU 21 reads out and acquires mounting condition information 44 on board S produced this time (S200). CPU 21 reads out mounting condition information 24 that is acquired from overall control device 19 and stored in storage section 23. Next, CPU 21 causes board processing section 26 to convey and fix board S to the mounting position (S210), and causes mounting head 32 to pick up component P (S220). Next, CPU 21 updates the number of uses of component P in component information 25 and outputs updated component information 25 to management device 14 (S230).

Next, CPU 21 causes imaging section 34 to image component P being picked up, acquires the pickup state of component P (S240), and causes head moving section 31 and mounting head 32 to put component P on board S when the pickup state is within an allowable range (S250). When the pickup state of component P is out of the allowable range, CPU 21 discards component P and executes the re-pickup of component P immediately after or after the discarding. Subsequently, CPU 21 determines the presence or absence of next component P to be disposed on board S (S260), and when next component P is present, CPU 21 executes the processing of S220 and thereafter, that is, the pickup of component P, the update of the number of uses, the check of the pickup state, and the disposition on board S. On the other hand, when there is no component P to be disposed on board S in S260, CPU 21 determines whether the production of the production type is completed (S270), and when the production is not completed, CPU 21 executes the processing of S210 and thereafter, that is, CPU 21 discharges board S and executes the conveyance, the fixation, and the mounting processing of next board S. On the other hand, when the production is completed in S270, the routine is finished. In this way, mounting device 15 executes the mounting processing of components P while updating the number of uses of component P.

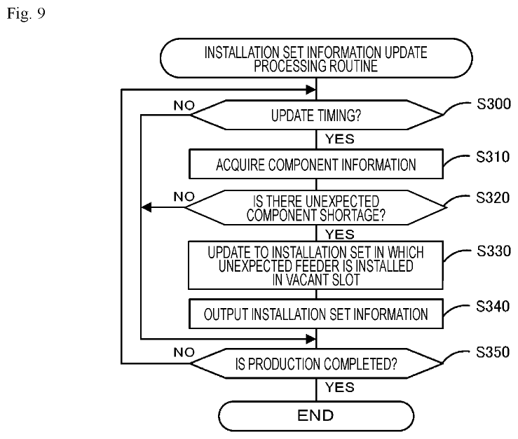

Next, update processing of installation set information 45 performed by management device 14 will be described. Management device 14 manages consumption of components P in mounting device 15, and outputs information on feeders 60 requiring supply, to preparation facility 17. FIG. 9 is a flowchart illustrating an example of an installation set information update processing routine executed by CPU 41 of management control section 40 provided in management device 14. This routine is stored in storage section 42 of management device 14 and is executed after mounting system 10 is started. When this routine is started, CPU 41 first determines whether an update timing of installation set information 45 is reached (S300). This timing can be set to, for example, time obtained by subtracting time at which feeder 60 can be prepared from time at which the supply preparation is completed, for example, 5 minutes before the time at which the supply preparation is completed. When the update timing is reached, CPU 41 reads out and acquires component information 47 (S310), and determines whether there is the unexpected component shortage (S320). In mounting device 15, there may be a case where the number of feeders 60 smaller than the number of components in the production plan is input, or there may be a case where the supply of feeder 60, which is not based on the production plan, is required due to frequent pickup errors of components P or the like. Here, CPU 41 detects such unexpected component shortage. When there is the unexpected component shortage, CPU 41 sets again installation set 46 for installing new feeder 60 for supplying component P of feeder 60 in which the unexpected component shortage occurs, in the vacant slot of magazine 65 to update installation set information 45 (S330), and outputs updated installation set 46B to preparation PC 70 disposed in preparation facility 17 (S340).

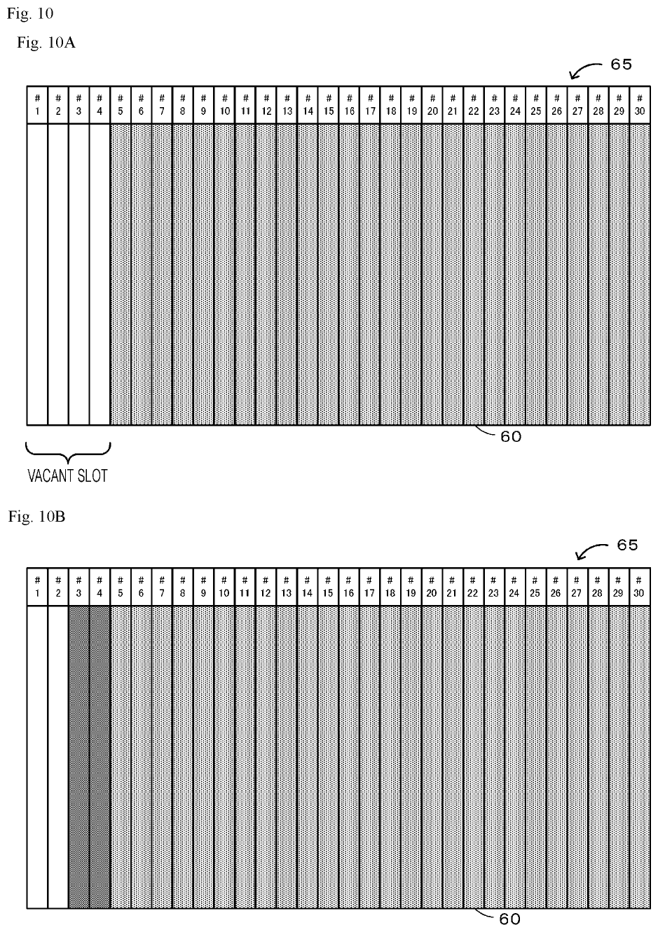

In a case where updated installation set information 45 is acquired, preparation PC 70 displays updated installation set information 45 on display section 76 (see FIG. 6B). Management control section 40 indirectly displays and outputs installation set 46 on display section 76 via preparation PC 70. Worker W, who has checked this display output, installs feeder 60 for supplying the unexpected component shortage in the vacant slot. FIGS. 10A and 10B are diagrams illustrating an example of supplying unexpected feeder 60 to the magazine, FIG. 10A shows magazine 65 before installation set 46 is updated, and FIG. 10B is a diagram of magazine 65 after installation set 46 is updated. As illustrated in FIG. 10B, since magazine 65 is always provided with the vacant slot, feeder 60 can be easily supplied to storage device 13 or mounting device 15 even when such unexpected component supply is required.

After S340, or when the update timing is not reached in S300, or when there is no unexpected component shortage in S320, CPU 41 determines whether the production is completed (S350), and when the production is not completed, CPU 41 executes the processing of S300 and thereafter. On the other hand, when the production is completed in S350, CPU 41 finishes the routine.

Next, exchange processing of feeder 60 executed by loader 18 will be described. Loader 18 exchanges and moves feeder 60 among mounting installation section 28, buffer installation section 29, and magazine 65 of storage device 13 based on a command from management device 14. Loader 18 serves feeder 60 for supply for buffer installation section 29 in advance before the exchange. At the exchange timing, loader 18 moves feeder 60 of mounting installation section 28 to buffer installation section 29, and moves feeder 60 for supply from buffer installation section 29 to mounting installation section 28. In addition, loader 18 moves used feeder 60 from buffer installation section 29 to storage device 13 in a time zone in which the exchange processing is not required. In this way, in mounting system 10, it is possible to continue the mounting processing while further suppressing the device stop due to the component shortage.

Here, a correspondence relationship between the elements of the present embodiment and the elements of the present disclosure will be clarified. Mounting device 15 of the present embodiment corresponds to a mounting device, management device 14 corresponds to an information processing device, preparation facility 17 corresponds to a preparation facility, loader 18 corresponds to a mobile work device, feeder 60 corresponds to a component supply device, and mounting system 10 corresponds to a mounting system. Management control section 40 corresponds to a control section, magazine 65 corresponds to a magazine, slot 67 corresponds to a slot, installation set 46 corresponds to an installation set, production plan information 43 corresponds to production plan information, and board S corresponds to a processing target object. In the present embodiment, an example of an information processing method of the present disclosure is also clarified by describing the operation of management control section 40.

In management device 14 as the information processing device described above, for magazine 65 including multiple slots 67 in which feeders 60 configured to supply components P are installed, installation set 46 including the installation slot in which feeder 60 is installed and the vacant slot in which feeder 60 is not installed is set, and installation set information 45 including set installation set 46 is output. For example, in mounting system 10, when magazine 65 in which multiple feeders 60 are installed is used, the installation of feeders 60 in all slots 67 of magazine 65 is more efficient in serving feeders 60. Meanwhile, in mounting device 15, the unexpected component shortage may occur, and there is a problem in how feeder 60 is served in this case. As described above, in a case where management device 14 performs operation with magazine 65 in which feeders 60 are fully installed, in a case where unexpected feeder 60 is added to magazine 65, an enormous amount of recalculation is required for installation set information 45 as the serving plan in the production, and furthermore, there may be a case where feeder 60 installed in magazine 65 is exchanged or the like, and it is not possible to sufficiently take a countermeasure. In management device 14, since feeder 60 is served by installation set 46 including the vacant slot, it is possible to flexibly take a countermeasure for the unexpected component shortage or the like, and to more appropriately supply feeder 60.

Further, since management control section 40 sets the vacant slot for magazine 65 and sets the installation slot for remaining slot 67 based on production plan information 43, the vacant slot can be set more reliably and a more appropriate installation slot can be set. Further, multiple types of feeders 60A and 60B having different widths can be installed in magazine 65, and management control section 40 sets the vacant slot in which at least one feeder 60 can be installed, so that it is possible to flexibly take a countermeasure even in a case where various feeders 60 are desired to be supplied. Furthermore, since management control section 40 sets the vacant slot in which multiple standard feeders 60 can be installed, it is possible to flexibly take a countermeasure even in a case where multiple standard feeders 60 are desired to be supplied. In addition, since management control section 40 sets the vacant slot of magazine 65 in a range equal to or lower than the predetermined occupancy rate set in advance, the occupancy rate of the vacant slot is set to an appropriate range, and thus it is possible to execute the supply of feeder 60 more efficiently. For example, the occupancy rate of the vacant slot is preferably higher when the unexpected component supply device is temporarily incorporated, and is preferably lower in a normal state, and can be set in a range equal to or higher than 5% and equal to or lower than 20%. The occupancy rate can be appropriately set to an appropriate range in accordance with the efficiency in a normal state or the ease of handling in an emergency.

In addition, since management control section 40 sets installation set 46 in which feeder 60 for component supply is installed in the vacant slot in unexpected component supply during production, for example, in a case of the unexpected component shortage, by setting the installation set in which feeder 60 for component supply is installed in the vacant slot, feeder 60 can be more appropriately supplied.

Further, mounting system 10 includes storage device 13 that stores feeders 60, and loader 18 as a mobile work device that exchanges feeders 60 between storage device 13 and mounting device 15, and management control section 40 outputs installation set 46 of magazine 65 to be moved to storage device 13. Management device 14 can more appropriately supply feeder 60 in mounting system 10 including storage device 13 and loader 18. Further, since management control section 40 outputs installation set 46 to preparation facility 17 in which feeder 60 is installed and magazine 65 is prepared, output installation set 46 can be used in preparation facility 17 in which feeder 60 is prepared. Furthermore, since management control section 40 displays and outputs installation set 46, worker W can visually recognize installation set 46 and can prepare feeder 60 while checking the information on installation set 46. Management control section 40 may cause the display section provided in management device 14 to display and output the information on installation set 46, or may cause any one of the display sections provided in mounting system 10 to indirectly display and output the information on installation set 46. In addition, mounting system 10 includes mounting device 15 that performs mounting processing on board S as the processing target object, and management device 14 as the information processing device. Since mounting system 10 includes management device 14 described above, feeder 60 can be more appropriately supplied.

In addition, in management device 14, since feeder 60 for supply can be quickly installed in the vacant slot of magazine 65, it is possible to minimize a serving delay of feeder 60 for magazine 65 due to the unexpected component shortage. Further, since it is possible to further suppress a deviation of the production plan due to the unexpected component shortage, it is possible to minimize a serving plan deviation of components due to the unexpected component shortage. Furthermore, since it is possible to predict the unexpected component shortage based on the number of uses of component P, it is possible to change the serving plan of feeder 60 for magazine 65 in accordance with the number of uses of component P or the number of discarded components P.

It is obvious that the present disclosure is not limited to the embodiment described above, and can be practiced in various aspects as long as the aspects belong to the scope of the present disclosure.

For example, in the embodiment described above, management control section 40 sets the vacant slot in which multiple standard feeders 60 can be installed among multiple types of feeders 60 having different widths, but the configuration is not particularly limited, and the vacant slot in which multiple non-standard feeders 60 can be installed may be set, or the vacant slot in which one feeder 60 can be installed may be set. Further, in the embodiment described above, management control section 40 sets the vacant slot of magazine 65 in a range equal to or lower than the predetermined occupancy rate set in advance, but the occupancy rate need not be particularly defined. Further, in mounting system 10, in a case where the vacant slot is set, a method of setting the vacant slot can be optionally determined.

In the embodiment described above, mounting system 10 includes storage device 13 and loader 18, and sets the installation set of magazine 65 to be moved to storage device 13, but the configuration is not particularly limited to this, and mounting system 10 need not include storage device 13 and loader 18, and may directly move magazine 65 to the installation section of supply section 27. Also in mounting system 10, since feeder 60 is served by setting installation set 46 including the vacant slot, it is possible to flexibly take a countermeasure for the unexpected component shortage or the like, and to more appropriately supply feeder 60.

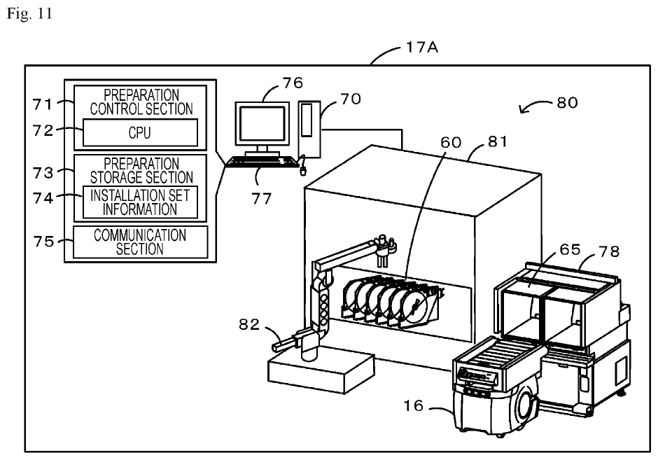

In the embodiment described above, installation set 46 is output to preparation PC 70, and worker W checks installation set 46 to prepare feeder 60, but the configuration is not limited to this, and for example, work in preparation facility 17 may be automated. In this case, preparation control section 71 may output installation set 46 to preparation device 80 which is disposed in preparation facility 17A and executes processing of installing feeder 60 and preparing magazine 65. FIG. 11 is a diagram illustrating an example of another preparation facility 17A. In preparation facility 17A, configurations similar to those of preparation facility 17 described above are denoted by the same reference numerals, and the description thereof will not be repeated. Preparation facility 17A includes preparation PC 70 and preparation device 80. Preparation device 80 is a device that performs processing of preparing feeder 60 and automatically installing prepared feeder 60 in predetermined slot 67 of magazine 65. Preparation device 80 includes feeder preparation section 81 and feeder removal section 82. Preparation PC 70 may control entire preparation device 80. Feeder preparation section 81 is a device that executes processing of installing reel 62 on vacant feeder 60 and registering information on component P in the controller. Feeder preparation section 81 accommodates multiple vacant feeders 60 and multiple reels 62 having various tapes 61 holding various components. Feeder preparation section 81 accommodates therein a moving section that moves reel 62, a moving section that moves feeder 60, and a device that sets reel 62 on feeder 60. Prepared feeder 60 is fed out to a carry-in/out port provided in the front of the device. Feeder removal section 82 is an arm robot that moves feeder 60 and executes work of installing feeder 60 in magazine 65. A mechanical chuck for gripping feeder 60 is provided at the distal end of the arm. In a case where installation set 46 is received from management device 14, preparation control section 71 of preparation PC 70 sets the vacant slot as included in the information, and causes feeder preparation section 81 and feeder removal section 82 to execute processing of installing prepared feeder 60 in the installation slot. In preparation facility 17A, preparation PC 70 and preparation device 80 can prepare feeder 60 while checking the information on installation set 46. In preparation facility 17A, since preparation device 80 executes the work of worker W, the work amount of worker W is reduced, and feeder 60 can be prepared more reliably.

In mounting system 10 described above, installation set 46 is displayed and output, but the configuration is not particularly limited to this as long as installation set 46 can be used. For example, voice output may be applied, printing output may be applied, or information itself on installation set 46 may be output to preparation PC 70 as in preparation facility 17A described above.

In the embodiment described above, the description is made in which management device 14 has the functions of the information processing device of the present disclosure, but the configuration is not particularly limited to this, and the configuration is not limited to this as long as installation set 46 is set. For example, one or more of mounting control section 20 of mounting device 15, overall control section 90 of overall control device 19, and preparation control section 71 of preparation PC 70, or other devices may have the functions of the information processing device of the present disclosure.

In the embodiment described above, the present disclosure is applied to the forms of mounting system 10 and management device 14, but the present disclosure may be applied to the information processing method, and a program causing a computer to execute respective steps of the information processing method may be applied.

Here, the information processing method of the present disclosure may be configured as follows. For example, the information processing method of the present disclosure is an information processing method used in a mounting system including a mounting device configured to perform mounting processing on a processing target object, the information processing method including: a step (a) of setting, for a magazine including multiple slots in which component supply devices configured to supply components are installed, an installation set including an installation slot in which the component supply device is installed and a vacant slot in which the component supply device is not installed: and a step (b) of outputting the installation set that is set in the step (a).

In the information processing method, as in the information processing device described above, it is possible to flexibly take a countermeasure for an unexpected component shortage or the like by the installation set including the vacant slot, and to more appropriately supply the component supply device. In this information processing method, various aspects of the information processing device described above may be adopted, or steps for achieving the functions of the information processing device described above may be added.

### INDUSTRIAL APPLICABILITY

The present disclosure is applicable to the technical field of a device that picks up and mounts a component.

### REFERENCE SIGNS LIST

10: mounting system, 11: printing device, 12: printing inspection device, 13: storage device, 14: management device, 15: mounting device, 16: automatic conveyance vehicle, 17, 17A: preparation facility, 18: loader (mobile work device), 18a: X axis rail, 19: overall control device, 20: mounting control section, 21: CPU, 23: storage section, 24: mounting condition information, 25: component information, 26: board processing section, 27: supply section, 28: mounting installation section, 29: buffer installation section, 30: mounting section, 31: head moving section, 32: mounting head, 33: pickup member, 34: imaging section, 35: communication section, 38: slot, 39: connection section, 40: management control section, 41: CPU, 42: storage section, 43: production plan information, 44: mounting condition information, 45: installation set information, 46: installation set, 47: component information, 48: communication section, 50: movement control section, 51: CPU, 53: storage section, 54: accommodation section, 55: exchange section, 56: moving section, 57: communication section, 60, 60A, 60B: feeder, 60a: rail member, 61: tape, 62: reel, 63: feeding mechanism, 64: connector, 65: magazine, 66: housing, 67: slot, 68: connection section, 69: connector, 70: preparation PC, 71: preparation control section, 72: CPU, 73: preparation storage section, 74: installation set information, 75: communication section, 76: display section, 77: input device, 78: storage device, 80: preparation device, 81: feeder preparation section, 82: feeder removal section, 90: overall control section, 91: CPU, 92: storage section, 93: communication section, 99: network, P: component, S: board, W: worker

1. An information processing device used in a mounting system including a mounting device configured to perform mounting processing on a processing target object, the information processing device comprising:
a control section configured to set, for a magazine including multiple slots in which component supply devices configured to supply components are installed, an installation set including an installation slot in which the component supply device is installed and a vacant slot in which the component supply device is not installed, and output the set installation set.

2. The information processing device according to claim 1,
wherein the control section is configured to set the vacant slot for the magazine, and set the installation slot for remaining slots based on production plan information.

3. The information processing device according to claim 1,
wherein multiple types of the component supply devices having different widths are installable in the magazine, and
the control section is configured to set the vacant slot in which multiple standard component supply devices are installable.

4. The information processing device according to claim 1,
wherein the control section is configured to set the vacant slot of the magazine in a range equal to or lower than a predetermined occupancy rate set in advance.

5. The information processing device according to claim 1,
wherein the control section is configured to set, at time of unexpected component supply during production, the installation set for installing the component supply device for the component supply in the vacant slot.

6. The information processing device according to claim 1,
wherein the mounting system includes a storage device configured to store the component supply device, and a mobile work device configured to exchange the component supply device between the storage device and the mounting device, and
the control section is configured to output the installation set of the magazine to be moved to the storage device.

7. The information processing device according to claim 1,
wherein the control section is configured to output the installation set to a preparation facility in which the component supply device is installed and the magazine is prepared.

8. The information processing device according to claim 7,
wherein the control section is configured to output the installation set to a preparation device disposed in the preparation facility and configured to execute processing of installing the component supply device and preparing the magazine.

9. The information processing device according to claim 1,
wherein the control section is configured to display and output the installation set.

10. A mounting system comprising:
a mounting device configured to perform mounting processing on a processing target object; and
the information processing device according to claim 1.

11. An information processing method used in a mounting system including a mounting device configured to perform mounting processing on a processing target object, the information processing method comprising:
a step (a) of setting, for a magazine including multiple slots in which component supply devices configured to supply components are installed, an installation set including an installation slot in which the component supply device is installed and a vacant slot in which the component supply device is not installed; and
a step (b) of outputting the installation set that is set in the step (a).
